(19) United States
(12) Patent Application Publication
(10) Pub. No.: US 2025/0046711 A1
(43) Pub. Date: Feb. 6, 2025

(54) LOW RESISTANCE ENHANCED ASPECT RATIO CONNECTOR FOR SEMICONDUCTOR DEVICE ASSEMBLY

(71) Applicant: Micron Technology, Inc., Boise, ID (US)

(72) Inventors: Shyam Surthi, Boise, ID (US); Richard J. Hill, Boise, ID (US)

(21) Appl. No.: 18/782,634

(22) Filed: Jul. 24, 2024

Related U.S. Application Data
(60) Provisional application No. 63/530,359, filed on Aug. 2, 2023.

(51) Int. Cl. H01L 23/528; G11C 16/04; H01L 23/00; H01L 23/522; H01L 25/065; H10B 41/20; H10B 41/35; H10B 43/20; H10B 43/35; H10B 80/00

(52) U.S. Cl. CPC H01L 23/5283; G11C 16/0483; H01L 23/5226; H01L 24/08; H01L 25/0657; H10B 41/20; H10B 41/35; H10B 43/20; H10B 43/35; H10B 80/00; H01L 2224/08145; H01L 2225/06541

(57) ABSTRACT

A semiconductor device assembly including a substrate; a plurality of functional devices disposed above the substrate; and a memory device disposed above the plurality of functional devices, the memory device including one or more memory arrays, a plurality of first vertical electrical connectors having a first diameter and extending vertically, and a plurality of second vertical electrical connectors having a second diameter and extending vertically, wherein the second diameter is greater than the first diameter.

### CROSS-REFERENCE TO RELATED APPLICATION(S)

The present application claims priority to U.S. Provisional Patent Application No. 63/530,359, filed Aug. 2, 2023, the disclosure of which is incorporated herein by reference in its entirety.

### TECHNICAL FIELD

The present disclosure generally relates to low resistance connectors, and more particularly relates to vertical connectors with enhanced aspect ratios in semiconductor device assembly.

### BACKGROUND

Advanced semiconductor devices, such as 3D NAND flash memory devices, utilize various technologies in assembling the memory cells/layers and control circuitry in one package to achieve higher memory storage density, smaller die size, and/or improved data transfer rate. For example, the CMOS-under-Array (CuA) technology places a CMOS logic layer on a ground floor of a 3D NAND memory stack to coordinate the read and write operations of the memory stack disposed there above. In another example, the Pads on Array (POA) Wafer-on-Wafer (WOW) packaging scheme bonds a frontside surface of a memory array wafer to a frontside surface of a CMOS logic wafer through a hybrid bonding technique, enabling fabrications of the memory array wafer and CMOS logic wafer separately to avoid thermal processing restraints. In these semiconductor device assemblies, critical signals including control signals and power signals are transmitted through (1) the memory stack disposed in a higher or an overlapping region of the packaging and (2) intermediate metal routing layers and to corresponding CMOS devices disposed in a lower region of the packaging. The performance of the semiconductor devices may be impacted by a size/or a dimension of the path or the physical medium used to convey the critical signals (e.g., connection path having a high aspect ratio (HAR)).

### BRIEF DESCRIPTION OF THE DRAWINGS

FIG. 1A depicts a schematic view of a semiconductor device assembly with a CuA stacking architecture.

FIG. 1B depicts a schematic view of another semiconductor device assembly with a POA face to face (F2F) WOW architecture.

FIGS. 2A through 2H depict various stages of processing a semiconductor device with one or more vertical connectors according to embodiments of the present technology.

FIGS. 3A through 3C depict various stages of processing a first example memory array wafer having one or more vertical connectors according to embodiments of the present technology.

FIGS. 4A through 4C depict various stages of processing a second example memory array wafer having one or more vertical connectors according to embodiments of the present technology.

FIGS. 5A through 5F depict various stages of processing a memory array wafer having one or more vertical connectors and a plurality of connector interconnects disposed according to embodiments of the present technology.

FIG. 6A through 6C illustrate various lithography hard mask patterns for fabricating one or more cluster connector vias according to embodiments of the present technology.

FIGS. 7A through 7C depict various stages of processing a semiconductor device assembly with one or more cluster connector vias according to embodiments of the present technology.

FIGS. 8A through 8C illustrate merging of cluster connect vias in a semiconductor device assembly corresponding to the lithography hard mask patterns of FIGS. 6A through 6C, respectively, according to embodiments of the present technology.

FIG. 9 is a flow chart illustrating a method of processing a semiconductor device assembly with one or more vertical connectors according to embodiments of the present technology.

FIG. 10 is a schematic view of a system that includes a semiconductor device configured according to embodiments of the presented technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

In advanced semiconductor devices including memory devices and logic devices, critical signals such as data signals and power signals can be transmitted using contacts, traces, connectors, and/or vias. Given the overall architecture, the critical signals can traverse along vertical directions, such as through a memory stack in memory devices to reach a control circuit for various operations. As the number of circuit layers increase (e.g., increases in memory layers for higher memory storage capability of memory devices), the aspect ratio of connectors used to transfer critical signals is also increases. The change in the aspect ratio (e.g., the ratio between height and width of a structure in the semiconductor device) can cause a higher contact resistance and risk of degrading the device performance. Further, lowering the contact resistance is beneficial in increasing the operating speeds for advanced semiconductor devices.

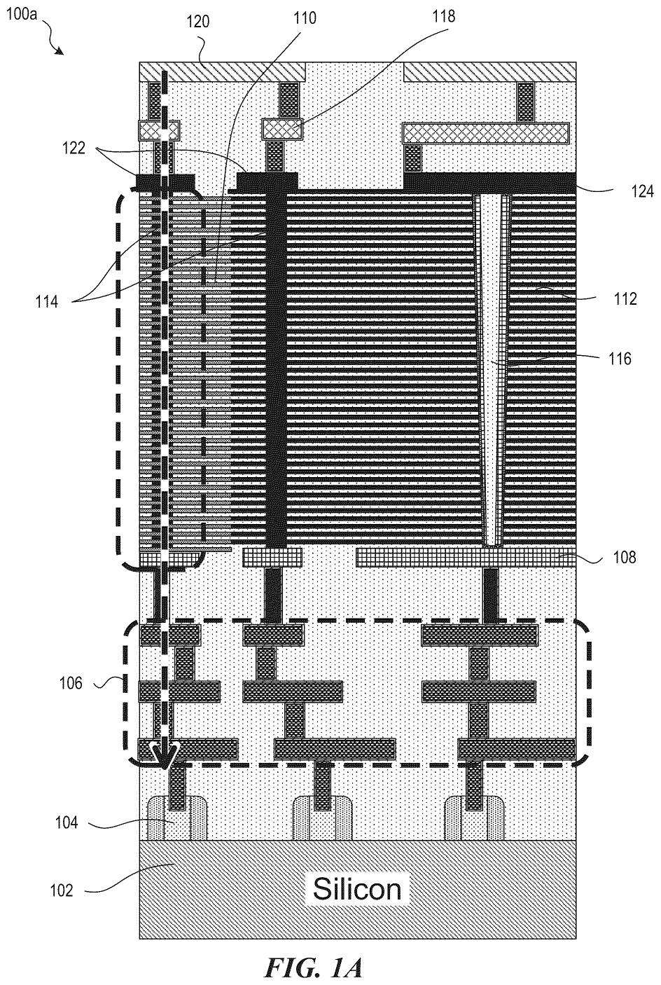

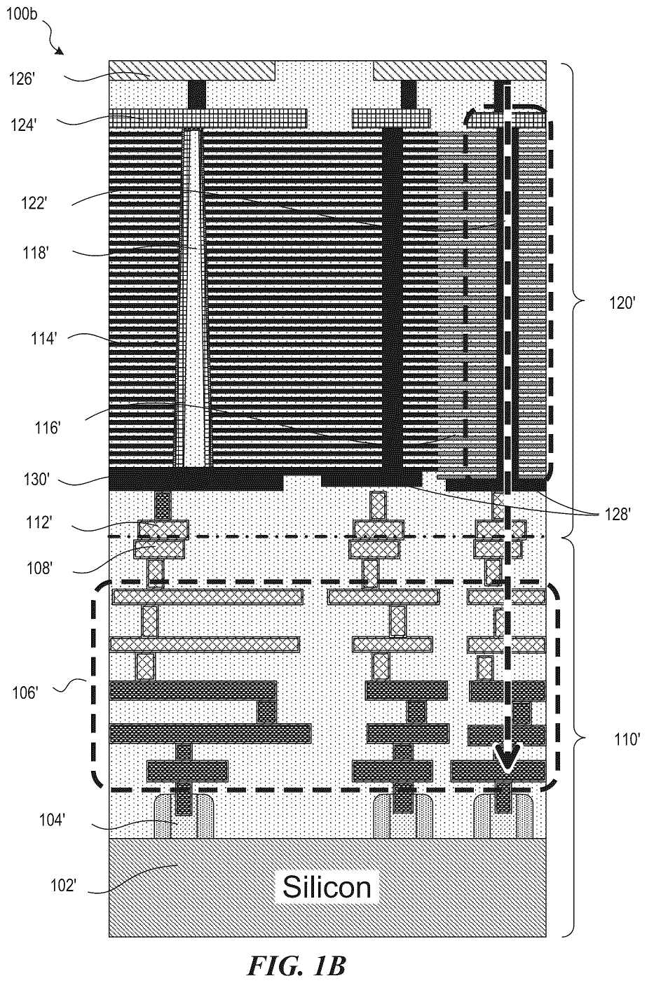

FIG. 1A depicts an exemplary semiconductor assembly (e.g., a 3D NAND memory device assembly 100a having a CuA stacking architecture). As shown, a plurality of memory data storage layers is vertically stacked above a CMOS device module. The stacked arrangement can increase the capacity and increase the capacity of each memory cell layer in comparison to conventional NAND memory devices.

In this example, the CMOS device can be fabricated on a carrier substrate 102 such as silicon. A plurality CMOS devices 104 can be fabricated on a frontside surface of the substrate 102. Additionally, intermediate metal layers 106 can be disposed above the CMOS devices 104 to provide electrical interconnections with the memory layers. Multiple layers of memory cells, e.g., 176-layer flash memory, can be disposed above the CMOS device module, having the source region contacts (SRC) 108 connected to corresponding CMOS device 104 through the intermediate layers 106. Here, the memory data storage layers include a memory region 112 having functional memory cells and pillars 116 configured for transitions of control and data signals. Moreover, the memory data storage layers can also include a non-memory region 110 surrounding the memory region 112.

The semiconductor device assembly 100a can further include one or more vertically extending connectors 114. One or more of the connectors 114 can be configured to convey critical control signals or power signals transition. The connectors 114 of the non-memory region 110 can have a similar diameter (e.g., close to or smaller than 0.5 μm) in comparison to other vertical connectors, such as the pillars 116 of the memory region 112. The connectors 114 can be formed along with the other vertical connectors by etching through the memory multiple layers. As shown in FIG. 1A, the connectors 114 and pillars 116 can be further connected to bond pads 120 disposed on a frontside surface of the memory device assembly 100, through a route distribution layer (RDL) 118. The semiconductor device assembly 100a can also include bit lines 124 and periphery layers 122.

In the CuA architecture disclosed in FIG. 1A, critical signals (e.g., control signals and power signals) can be transferred to corresponding CMOS devices 104 through the connectors 114, as indicated by the arrow line. Here, the thickness of the memory storage layers can be close to 10 μm or greater, and the aspect ratio of the connectors 114 can be close to 10:1 or greater. In semiconductor device fabrication, aspect ratio is defined as a ratio of the height of a structure over the width of the structure. Usually, the higher the aspect ratio (e.g., with a HAR as defined by a predetermined threshold), the more challenging it is to manufacture the structure in electrical device. As an example, a vertical connector structure with a vertical dimension (e.g., a height) of 10 μm and a lateral dimension (e.g., a diameter in cross sectional plane) of 1 μm has an aspect ratio of 10:1. In this example, the CuA stacking architecture offers advantages in further scaling the memory device by increasing a quantity of flash memory layers. Meanwhile, the increase in the number of layers can correspondingly increase the aspect ratio it can provide (e.g., into a HAR category defined by a predetermined threshold, such as 10:1), thereby generating challenges to transferring critical signals through the memory layers of the memory device assembly 100. The HAR profile of the vertical connectors can increase the contact resistance for the critical signals, which in turn causes latencies in operating the memory device. In this example, the sizes of the pillars 116 and the connectors 114 may not be proportional as shown in FIG. 1A. For example, the pillars may have a width ranging from 0.1 μm to 0.15 μm. In another example, the connectors may have a width close to 0.5 μm.

In another example, FIG. 1B depicts another 3D NAND memory device assembly 100b having a POA F2F architecture. In some embodiments, the POA F2F memory device assembly 100b can be formed by bonding a frontside surface of a memory wafer to a frontside surface of a CMOS wafer through a hybrid bonding technique. The bonded wafers can be further singulated and packaged into individual semiconductor device assembly, such as the memory device assembly 100b in FIG. 1B. As shown, dielectric-dielectric bonding and metal-metal bonding can be formed at the interface of the memory device 100b and the CMOS device 110′.

In this example, the CMOS device 110′ includes a substrate 102′, a plurality of CMOS devices 104′ disposed above the substrate 102′, and a plurality of intermediate metal layers connected to corresponding CMOS devices 104′. The CMOS device 110′ can further include a plurality of bond pads 108′ disposed on a frontside surface of the CMOS device 110′. Additionally, the memory device 120′ can include a memory array having a memory region 114′ containing multiple layers of memory cells for data storage and a non-memory region 116′ that is disposed adjacent to the memory region 114′. The memory region 114′ and the non-memory region 116′ can include one or more pillars 118′ for data signal transition and one or more connectors 122′ for critical signals including control signals or power signals transition. The memory device 120′ may also include a plurality of bond pads 112′. The memory device 120′ can also include bit lines 130′ and periphery layers 128′.

A plurality of SRC nodes 124′ can be disposed above the memory array and connected to corresponding bond pads 126′. In this example, critical signals can be transmitted from the bond pad 126′, through the connector 122′, to corresponding CMOS devices 104′, as indicated by the dashed arrow. While the POA F2A memory device architecture provides a reduced manufacturing cost and the ability to form backside SRC, it still faces significant performance risk by passing critical signals through the memory array. As the quantity of memory layers increases to improve the overall storage capability, the resulting increase in the aspect ratio of the contact 122′ can increase the contact resistance, which in turn degrades the operation and data transfer rate in the memory device assembly 100′.

To address the above-described challenges and others, the present technology includes a low resistance connector for transmitting critical signals in the semiconductor device assembly. Specifically, a connector with an increased diameter, e.g., close to 1.5 μm or greater in comparison to 0.5 μm diameter for other conventional vertical connectors, can be fabricated through the memory device region of the semiconductor device assembly. The larger vertical connector can reduce the contact resistance as the thickness of the stacked layers and the corresponding aspect ratio of the vertical connectors increase. The larger connectors in memory device assembly can be formed through a sacrificial material fill flow to avoid thermal restraints in the fabrication processes. Alternatively, the larger connectors can be formed by forming a set of smaller vias according to a predetermined pattern and removing the structures remaining between the smaller vias. Specifically, the larger connectors can be formed by etching through the memory array to form the set of smaller vias that are connected to SRC nodes of the memory array. The set of smaller vias can be further merged into the larger connector vias. The resulted larger connectors have an overall diameter greater than conventional connectors, resulting a reduced aspect ratio of the larger connectors to achieve a low contact resistance for critical signal transition. Moreover, the fabrication processes included in the present technology are compatible to standard semiconductor manufacturing, adding little or no additional cost.

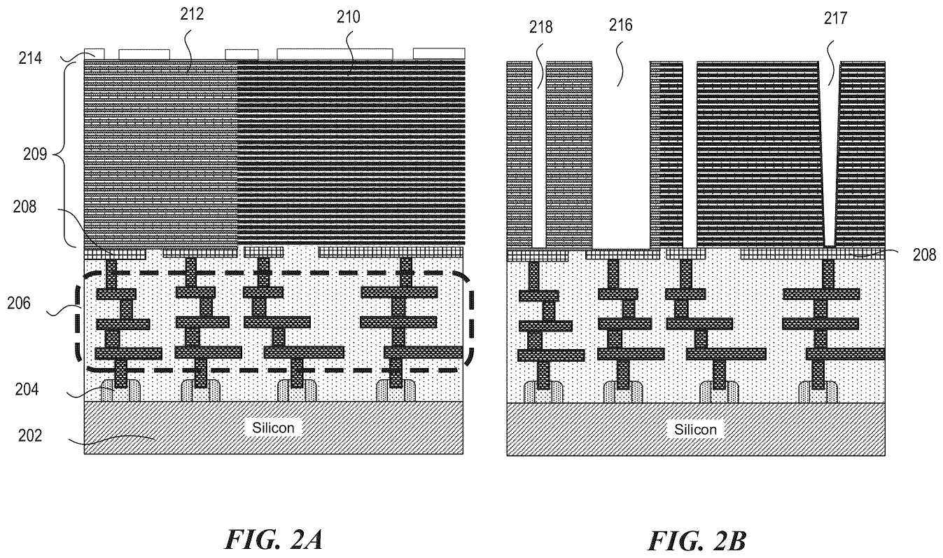

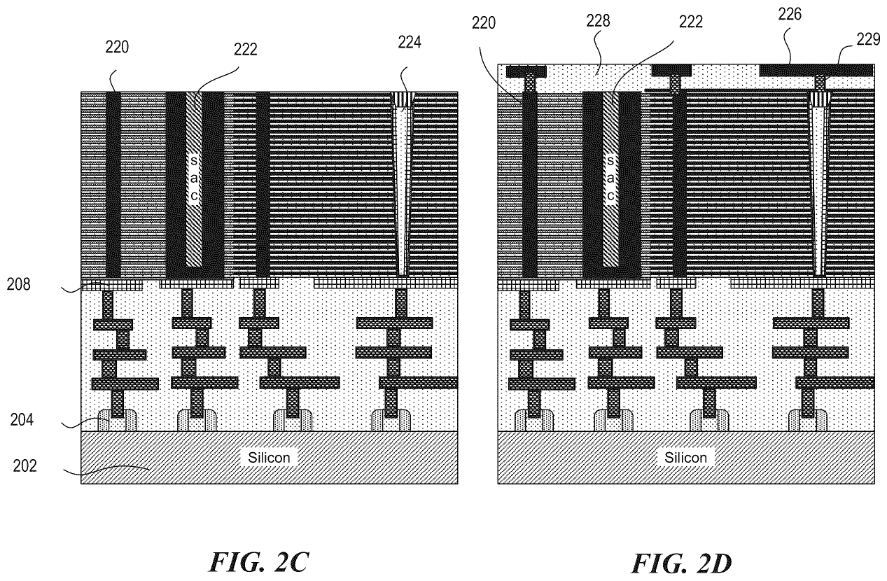

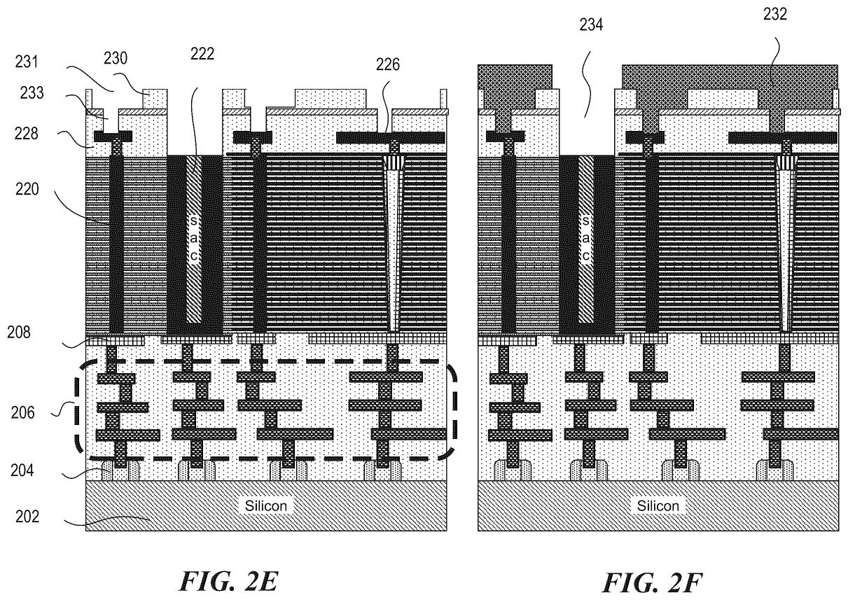

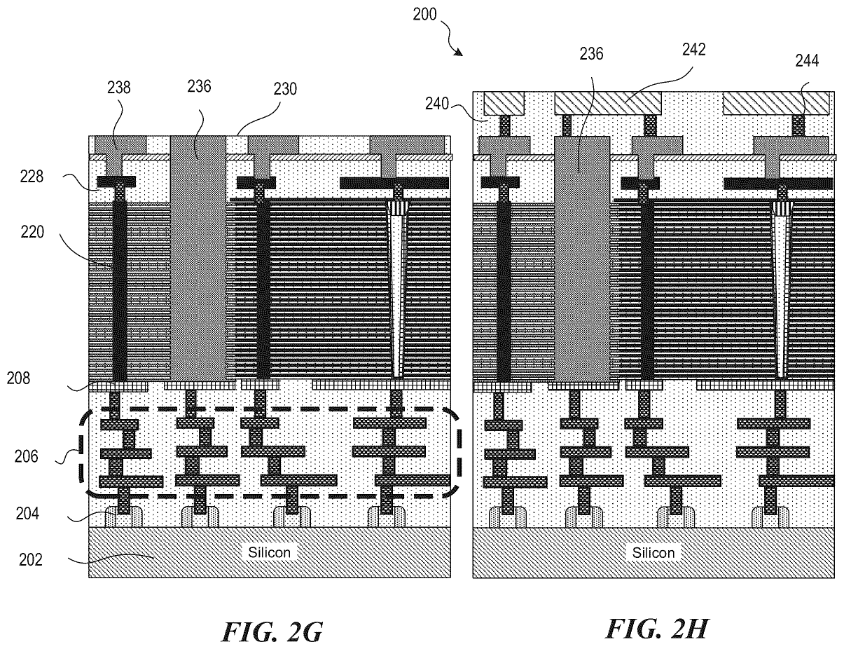

FIGS. 2A through 2H depict various stages of processing a semiconductor device 200 (e.g., a device or an assembly having a CuA architecture) with one or more connectors according to embodiments of the present technology. The semiconductor device 200 can be fabricated on a substrate 202 (e.g., a semiconductor substrate, such as a silicon substrate). As shown in FIG. 2A, CMOS devices 204 can be disposed above a frontside of the substrate 202. Additionally, each of the CMOS devices 204 can be connected to corresponding source region contact (SRC) 208 through a plurality of intermediate metal layers 206 (e.g., a set of lateral and/or vertical electrical connections). In some embodiments, the semiconductor device 200 can include a memory array disposed in an upper region and vertically stacked above the CMOS devices 204 according to the CuA architecture. The semiconductor device 200 can include one or more memory arrays 209, each of which can include a memory region 210 and a non-memory region 212. Both of the memory region 210 and the non-memory region 212 can be disposed above the intermediate metal layers 206 and the CMOS device 204. Specifically, as shown in FIG. 2A, the source region contacts 208 can be disposed on a backside of the memory region 210 and the non-memory region 212.

In the illustrated example, a patterned hard mask layer 214 can be formed or otherwise disposed above the memory array. In some embodiments, the hard mask layer 214 can be patterned, using a dedicated lithography mask, to form a plurality of openings that correspond to various connectors to be fabricated in the semiconductor device 200. The dedicated lithography mask can include one or more larger opening features (e.g., having a width close to 1.5 μm or greater in comparison to other openings with widths less than 1 μm or around 500 nm). The larger opening features can be aligned to the non-memory region 212. After patterning, the larger opening features can be transferred to the hard mask layer 214 in larger openings disposed above the non-memory region 212. In some other examples, the larger opening features of the lithography mask can be aligned to the memory region 210 and can be transferred to the hard mask layer 214 disposed above the memory region 210. Additionally or alternatively, the hard mask layer 214 can be a patterned photo resist layer. In the present technology, the dedicated lithography mask can be used to pattern openings in the photo resist layer through exposure to photo resist stripping processes.

In a next stage, various types of contact vias can be formed in the semiconductor device 200. As shown in FIG. 2B, the non-memory region 212 and the memory region 210 can be etched, through the patterned hard mask layer 214, to form connector via 218, connector via opening 216, and/or pillar via 217. The etching process can be done by a wet etching technique or an anisotropic etching technique, such as a reactive ion etch (RIE) process. In this example, the etching of various types of vias can be conducted in one fabrication step and stopped on the SRC 208 due to a high etching selectivity. Here, the connector via opening 216 can have a diameter (e.g., close to 1.5 μm or greater) larger than that of the connector via 218 and pillar via 217 (e.g., close to 500 nm or less). The diameters of various vias shown in FIG. 2B can be defined by and transferred from dimensions of opening features on the dedicated lithography mask. In this example, each of the connector via 218, connector via opening 216, and pillar via 217 can extend at least partially through the memory array, e.g., the non-memory region 212 or the memory region 210, and/or contact corresponding SRC 208. Once the various types of vias are formed, the hard mask layer 214 can be removed, such as by a selective wet etching process. In some other example, the connector via opening 216 can be formed in the memory region 210. In this example, the connector via 216 may be larger than the pillar via 217. For example, the connector via 216 may have a width close to 0.5 μm. In comparison, the pillar via 217 may have a width ranging from 0.1 μm to 0.15 μm. In some other examples, the pillar via 217 can be fabricated at a different masking step than the connector via 218 and connector via opening 216.

Once the connector vias are formed in the semiconductor device 200, they can be filled by electrically conductive materials to form vertical connectors. For example, suitable conductive metal such as aluminum, tungsten, cobalt, nickel, or any other suitable conductive materials can be filled into the connector via 218 and pillar via 217 to form the connector 220 and pillar 224, respectively. Additive process, including but not limited to, plating, depositing, or any other suitable method of manufacturing can be used here to fill conductive materials into the connector vias. As shown in FIG. 2C, the conductive material can be also formed on a sidewall and bottom surface of the connector via opening 216, which has a larger/wider opening in comparison to the contact via 218 and bit line via opening 216. Accordingly, the added conductive material in via opening 216 may have an indentation in a center portion, such as caused by adding limited or insufficient volume of conductive material in the larger via opening 216. Sacrificial materials 222 such as poly silicon or silicon oxide can be filled into the center or the indentation in the conductive material within the connector via opening 216. The sacrificial material 222 can close the top opening of the connectors via opening 216 and be pinched off at a top portion of the connector via opening 216.

In a next stage and as shown in FIG. 2D, a redistribution layer (RDL) 226 can be formed above the memory device region of the semiconductor device 200. Specifically, a dielectric layer 228 can be deposited above the memory array (e.g., over/overlapping the sacrificial material 222 and the conductive material in the connector via opening 216) of the semiconductor device 200. In some embodiments, the dielectric layer 228 can include silicon oxide or silicon nitride. The RDL 226 and interconnect 229 can be formed by patterning the dielectric layer 228 with openings/indentations and filling them with conductive materials such as aluminum, tungsten, cobalt, nickel, or any other suitable conductive materials. Notably, the RDL 226 can be connected to one or more connectors 220 and the pillars 224 for electrical interconnection. The connector via opening 216 and the conductive material and the sacrificial material 222 therein can be encapsulated by the dielectric layer 228 and disconnected from the conductors in the RDL 226.

In some embodiments, a dual damascene technique can be used to process copper pad in the semiconductor device 200. As shown in FIG. 2E, dielectric layers 230 and 228 can be patterned using a set of lithography masks to form trenches 231 and corresponding vias 233 disposed there below. Here, the trenches 231 can be patterned before the etching of the vias 233 (e.g., a trench first process) or after the fabrication of the vias 233 (e.g., a via first process). In this example, the connector via opening 216 filled with sacrificial material 222 can be exposed using the same set of lithography masks, through selectively etching the dielectric layers 230 and 228. In a next stage, the dual damascene copper structure can be protected and leave an opening 234 above the connector via opening 216. For example, as shown in FIG. 2F, photo resist 232 can be coated into the trenches 231 and vias 233 in order to protect the dual damascene structure from a following connector etching process.

Once the dual damascene trenches and vias are protected, the sacrificial material 222 and the connector 220 can be selectively removed from the connector via opening 216 through the opening 234. A selective wet etching process or anisotropic etching technique such as RIE can be utilized here to completely remove the sacrificial material 222 and the connector 220 in the via opening 216 through the top opening 234. Here, the etching process is selective between conductive connector material 220 and surrounding memory region or non-memory region materials. Thereafter, the photo resist 232 protecting the dual damascene trenches and vias can be removed, e.g., by a photo resist stripping process.

In a next stage, conductive materials such as copper can be filled into the dual damascene structure and the connector via opening 216. For example, as shown in FIG. 2G, copper pads 238 and corresponding copper interconnects can be formed above and connected to the RDL 226. In addition, a connector 236 can be formed by filling copper into the exposed connector via 226 using a metal deposition or plating process. The connector 236 can extend vertically, such as pass through the non-memory region 212, and connected to corresponding SRC 208. Here, the copper deposition can continue until the opening 234 is fully filled. Here, a chemical mechanical polishing (CMP) process can be implemented to planarize a top surface of the connector 236.

FIG. 2H illustrates a final metallization and bond pad fabrication process in processing the semiconductor device 200. As shown, a dielectric layer 240 can be deposited above the dielectric layer 230. The dielectric layer 240 can be further patterned to form trenches on its frontside surface. Conductive materials such as tungsten, cobalt, and/or nickel can be deposited into the trenches to form bond pads 242 on the frontside surface of the semiconductor device 200. The bond pad 242 can be connected to corresponding copper pads through the interconnect 244.

The above-described manufacturing flow can implement connectors, e.g., the larger vertical connector 236, into the semiconductor device 200 as a low contact resistance path for critical signal transition. Moreover, the filling of conductive material into the connectors can be conducted in a later time frame during the fabrication of the semiconductor device 200. This can help eliminate a thermal restraint (e.g., close to 400° C. from the contact copper) on the semiconductor device fabrication processes between the via etching and copper contact filling.

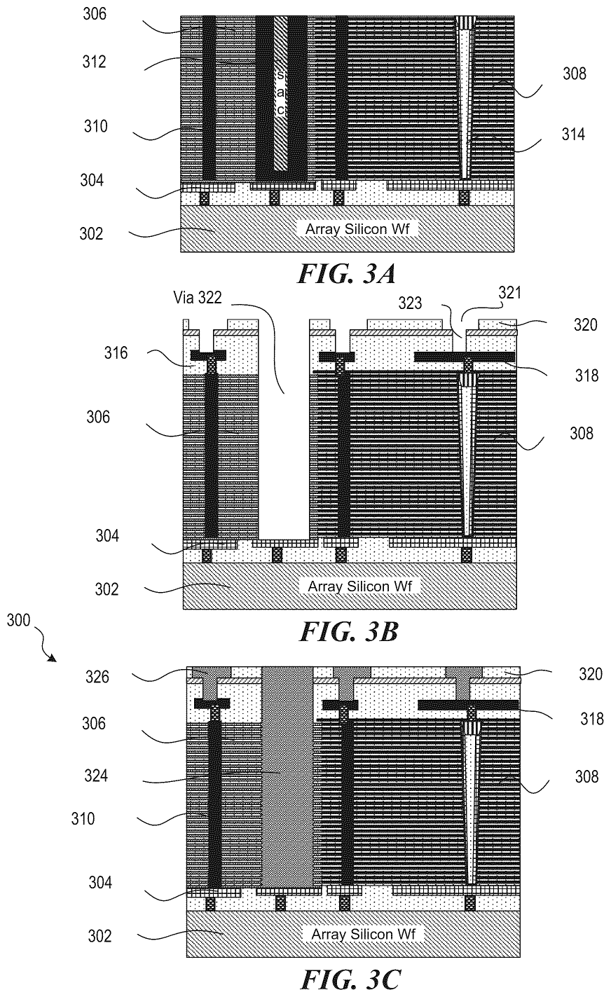

FIGS. 3A through 3C depict various stages of processing a memory array wafer 300 for semiconductor device assembly, e.g., POA F2F wafer-to-wafer bonding, according to embodiments of the present technology. The memory array wafer 300 can include one or more connectors, through which critical signals can be transmitted to corresponding circuit devices of a circuit wafer. The memory array wafer 300 can be bonded to the circuit wafer through the hybrid bonding technique to form the POA F2F semiconductor device assembly, similar to the semiconductor device shown in FIG. 1B.

In the memory array wafer 300, a memory array including a memory region 308 and a non-memory region 306 can be disposed above a substrate 302. A plurality of SRC 304 can be formed below the non-memory region 306 and the memory region 308. As shown in FIG. 3A, the memory array wafer 300 can be patterned to form various connector vias that can be filled by conductive materials to form a connector 310 and pillar 314. Particularly, a connector via 322 can be formed by etching through the non-memory region 306 with a larger top open CD (e.g., close to 1.5 μm or greater). In contrast, each of the connector 310 and the pillar 314 can have a diameter that is less than that of the larger top open CD by a factor of 2 or greater (e.g., close to 500 nm or less). In this example, conductive contact material can be formed on a sidewall and bottom surface of the connector via 322. In addition, sacrificial material 312 can be deposited into any depressions in the conductive material disposed on the sidewall of the connector via 322. In some other examples, the sacrificial material 312 can be pinched off in its top portion and include an embedded air gap. The pillars 314 may have a width ranging from 0.1 μm to 0.15 μm. In another example, the connectors 310 may have a width close to 0.5 μm.

In a next stage and as shown in FIG. 3B, dielectric layers 316 and 320 can be deposited on the frontside surface of the memory array wafer 300. RDL layer 318 can be formed by patterning the dielectric layer 316 and filling with conductive materials. In addition, the RDL layer 318 can be connected to the corresponding connector 310 or pillar 314. In this example, the dual damascene technique can be utilized to pattern the dielectric layers 316 and 320 and to form trenches 321 and vias 323 that are corresponding to RDL 318. Once the dual damascene structure is formed, it can be further protected by photo resist deposited there on. In a following process, the contact material 310 and sacrificial material 312 disposed in the connector 322 can be selectively removed. An opening through the dielectric layers 316 and 320 right above the connector via 322 can be formed by conducting a wet etching process or a RIE etch process there through. Relevant process details can be similar to those described above for FIGS. 2C through 2F. In some other examples, the connector via 322 can be formed in the memory region 308. For example, a hard mask layer with an opening close to 1.5 μm or greater can be formed above the memory region 308. The memory region 308 can be etched through the opening of the hard mask layer to form a connector via. The connector via can be connected to a SRC disposed below the memory region 308 and filled by conductive material to form a vertical connector for critical signals transition.

After the contact material 310 and sacrificial material 312 being removed from the connector via 322, the photo resist covering the trenches 321 and vias 323 can be removed, e.g., by a photo resist stripping process. As shown in FIG. 3C, copper can be filled into the connector via 322 to form a connector 324, vertically extending from corresponding SRC 304 all the way up to a frontside surface of the dielectric layer 320. In a single process, copper can be filled into the dual damascene structure including the trenches 321 and the vias 323 to form the copper bond pads 326. A CMP process can be utilized here to planarize the bond pads 326 and the connector 324 on the frontside surface of the memory array wafer 300.

In this example, the memory array wafer 300 can be bonded to a circuit wafer (not shown), e.g., a CMOS wafer, by a hybrid bonding technique. For example, the copper bond pads 326 of the memory array wafer 300 can be connected to bond pads of the CMOS wafer to form metal-metal bonds at the wafer interface. In addition, the dielectric layer 320 can be bonded to another dielectric layer of the CMOS wafer to form fusion covenant bonds there between. The CMOS wafer can include a bond pad that corresponds to the connector 324 of the memory array wafer 300. Bonding the memory array wafer 300 to the CMOS wafer forms a low contact resistance path through the connector 324 to transmit critical signals.

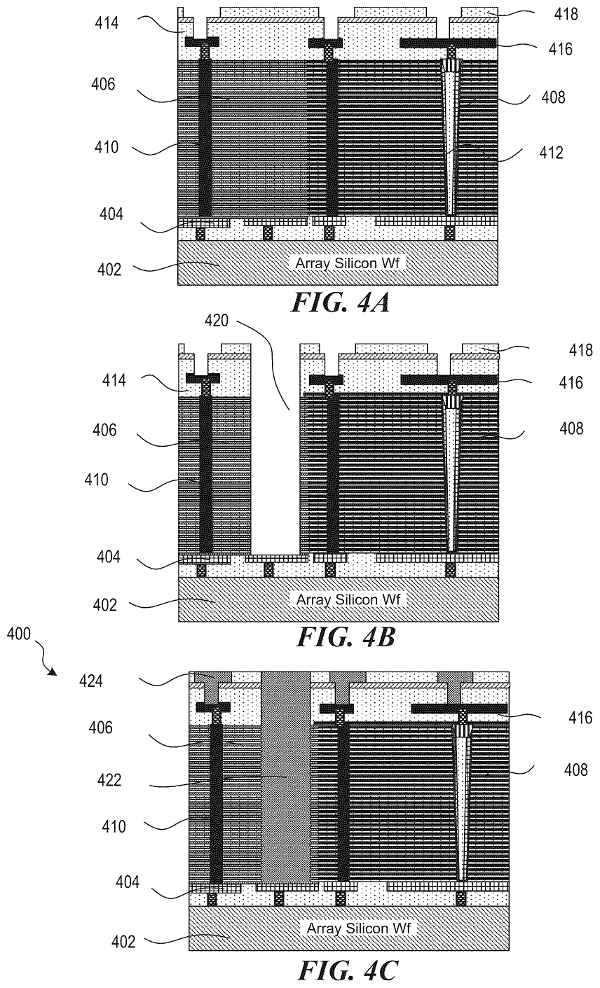

FIGS. 4A through 4C depict various stages of processing another memory array wafer 400 having one or more connectors according to embodiments of the present technology. In particular, the memory array wafer 400 utilizes a dedicated lithography mask to pattern a connector via opening 420 in order to form the connectors 422. In this example, the processes of the connectors 422 and other contacts 410 can be separated and a sacrificial material fill process can be omitted.

For example, FIG. 4A illustrates a memory array wafer 400 incoming to the semiconductor device assembly process. As shown, a non-memory region 406 and a memory region 408 can be fabricated in each of one or more memory arrays disposed above a substrate 402. A plurality of SRC 404 can be disposed under the non-memory region 406 and the memory region 408. Connector 410 and pillar 412 can be formed in the non-memory region 406 and the memory region 408, respectively. Specifically, the connector 410 and the pillar 412 can have a diameter close to 500 nm or less, and can be connected to corresponding SRC 404. In this example, a dielectric layer 414 can be deposited above the non-memory region 406 and the memory region 408. RDL layers 416 can be formed by patterning the dielectric layer 414 and filling with conductive materials. As shown, another dielectric layer 418 can be deposited on the frontside surface of the memory array wafer 400. A dual damascene process can be conducted to pattern the dielectric layers 418 and 414, forming trenches and vias for metal pad contacts. In this example, the pillars 412 may have a width ranging from 0.1 μm to 0.15 μm. In addition, the connectors 410 may have a width close to 0.5 μm.

Turning to FIG. 4B, a hard mask layer or a photo resist layer (not shown) can be coated above the frontside surface of the memory array wafer 400 in order to protect the dual damascene structures from downstream etch processes. Here, a dedicated lithography mask having a pattern corresponding to desired one or more connectors can be used to pattern the hard mask layer. As shown in FIG. 4B, a wet etching process or a RIE process can be conducted, through the patterned hard mask layer, to form the connector via opening 420. The connector via opening 420 can have a diameter, e.g., close to 1.5 μm or greater, larger than the contact 410 or the pillar 412. In this example, the connector via opening 420 can completely pass through the non-memory region 406 and be connected to corresponding SRC 404. The connector via opening 420 can have an aspect ratio close to 10:1 or less. In some other examples, the connector via opening 420 can be formed in the memory region 408.

In a next stage and as shown in FIG. 4C, the hard mask layer can be removed by a selective etch process. After that, conductive materials such as copper can be deposited into the connector via opening 420 and the trenches to form the connector 422 and the bond pads 424, respectively. A CMP process can be utilized here to planarize the frontside surfaces of the bond pads 424 and the connector 422. The memory array wafer 400 can be further bonded to a CMOS wafer through a hybrid bonding technique. In particular, the connector 422 can be bonded to a bond pad of the CMOS wafer to form a metal-metal fusion bond therebetween. The generated POA F2F WOW bonding architecture can form a low contact resistance path including the connector 422 of the memory array wafer 400, through which critical signals can be transmitted without delay.

The connector structures and process flows described above in FIGS. 4A through 4C can be formed or conducted on a CuA architecture. For example, the memory region 408 and non-memory region 406 described in FIGS. 4A-4C can be formed vertically above a CMOS wafer, having the SRC 404 electrically connected to corresponding CMOS devices in the CMOS wafer. The connector 422 can be formed similarly on the CuA architecture. Here, critical signals can be transmitted through the connector 422 to corresponding CMOS devices in the CuA semiconductor device.

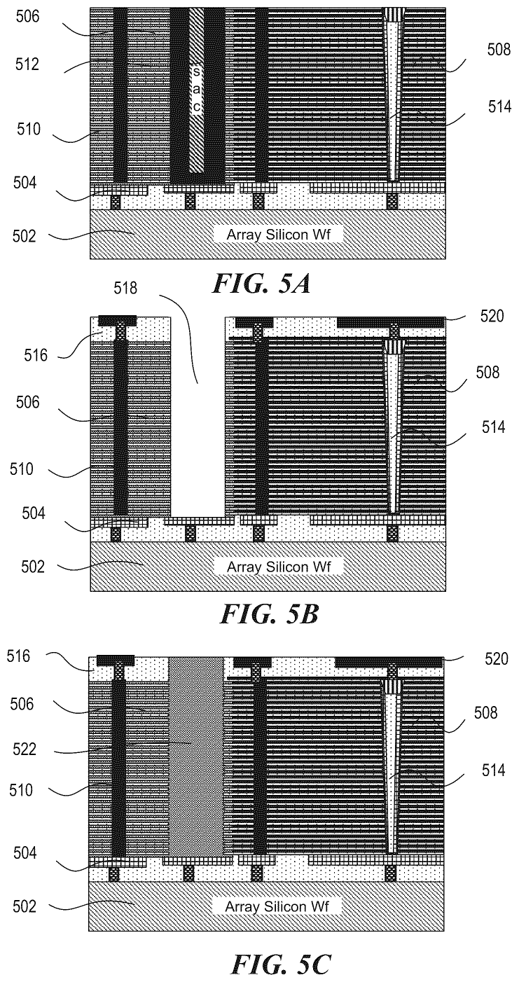

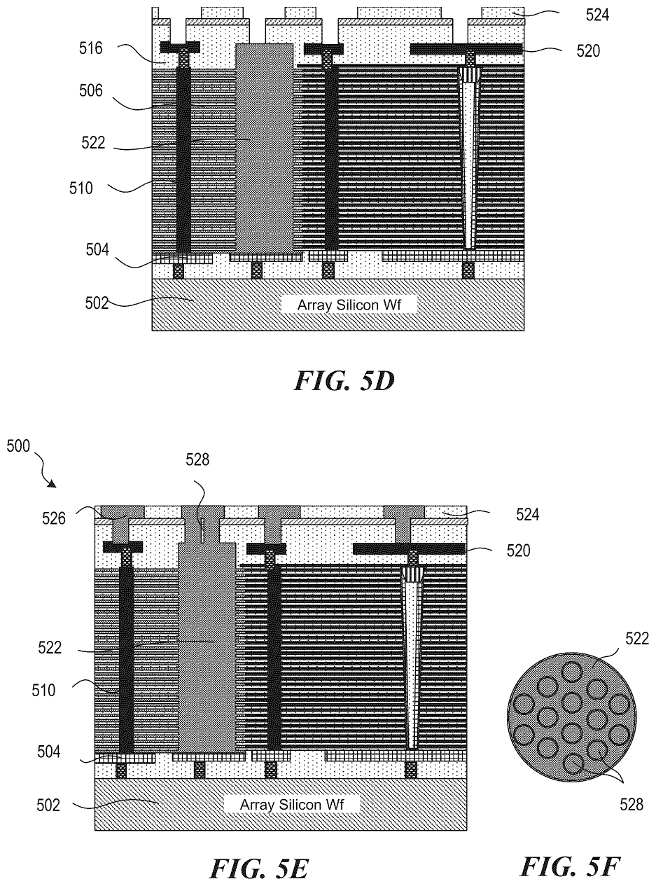

FIGS. 5A through 5F depict various stages of processing a memory array wafer 500. The memory wafer 500 can have a POA F2F wafer-to-wafer bonding architecture. In addition, the memory wafer 500 can have one or more larger connectors and a plurality of smaller interconnects disposed above each of the one or more connectors, according to embodiments of the present technology. In the memory array wafer 500, the memory array such as the memory region 508 as well as the non-memory region 506 can be disposed above a substrate 502. A plurality of SRC 504 can be formed below the non-memory region 506 and the memory region 508.

As shown in FIG. 5A, the memory array wafer 500 can be patterned to form various connector vias and filled by conductive materials to form a connector 510 and a pillar 514. For example, a connector via opening 518 can be formed by etching through the non-memory region 506 having a larger top open CD (e.g., having a width close to 1.5 μm or less in comparison to other openings with widths less than 1 μm or around 500 nm). In contrast, the connector 510 and pillar 514 can have a diameter close to 500 nm or less. Here, conductive material can be deposited on a sidewall and bottom surface of the connector via opening 518. In addition, sacrificial material 512 can be deposited into the connector via opening 518 and completely fill out the space between conductive material disposed on the sidewall. In some other examples, the sacrificial material 512 can be pinched off in its top portion and include an embedded air gap. In this example, the pillars 514 may have a width ranging from 0.1 μm to 0.15 μm. In addition, the connectors 510 may have a width close to 0.5 μm.

In a next stage, dielectric layer 516 can be deposited on the frontside surface of the memory array wafer. As shown in FIG. 5B, RDL layer 520 can be formed by patterning the dielectric layer 516 and filling with conductive materials. In addition, the RDL layer 520 can be connected to corresponding connectors 510 or pillar 514. In this example, the dielectric layer 516 can be disposed above the memory array via opening 518 and have an opening over the connector via opening 518. Here, the connector via opening 518 can extend from a top surface of the dielectric layer 516 to the SRC 504, having an aspect ratio close to 10:1 or less. In some other examples, the connector via opening 518 can be formed in the memory region 508.

FIG. 5C illustrates that conductive materials such as copper can be filled into the connector via opening 518 to form the connector 522. In some embodiments, the connector 522 can have a diameter close to 1.5 μm or greater (e.g., wider than a factor of 2 or greater in comparison to other conventional vertical connectors). In this example, a CMP process can be utilized to planarize the top surface of the memory array wafer 500.

In a next stage and as shown in FIG. 5D, dielectric material 516 and 524 can be further deposited on the front side surface of the memory array wafer 500. The dual damascene technique can be used here to form trenches and vias within the dielectric layers 516 and 524. As shown in FIG. 5E, conductive materials such as copper can be filled into the trenches and vias, forming metal pad 526 on the frontside surface of the memory array wafer 500. A CMP process can be conducted to planarize the mental pad 526. In this example, the dual damascene process can form a plurality of small vias above the connector 522, each of which having a diameter ranging from 50 nm to 200 nm. Conductive materials such as copper can be filled into the plurality of small vias to form the connector interconnects 528. Here, the connector interconnects 528 can electrically connect the connector 522 and the metal pad 526 disposed there above. FIG. 5F illustrate a top plan view of the connector interconnects 528 over the connector 522. As shown, each of the connector interconnects 528 has a diameter smaller than the connector 522. The multiple smaller connects included in the connector interconnects 528 can help avoid bottleneck in transferring critical signals from the metal pad 526 to the connector 522.

The connector structure and process flow described above in FIG. 5A to FIG. 5F can be formed or conducted on a semiconductor device assembly CuA architecture. For example, the memory region 508 and non-memory region 506 described in FIGS. 5A-5E can be formed vertically above a CMOS wafer, having the SRC 504 electrically connected to corresponding CMOS devices of the CMOS wafer. The connector 522 as well as the connector interconnects 528 can be formed similarly on the CuA architecture. Here, critical signals can be transmitted through the metal pad 526 and connector 522 to corresponding CMOS devices in the semiconductor device having the CuA architecture.

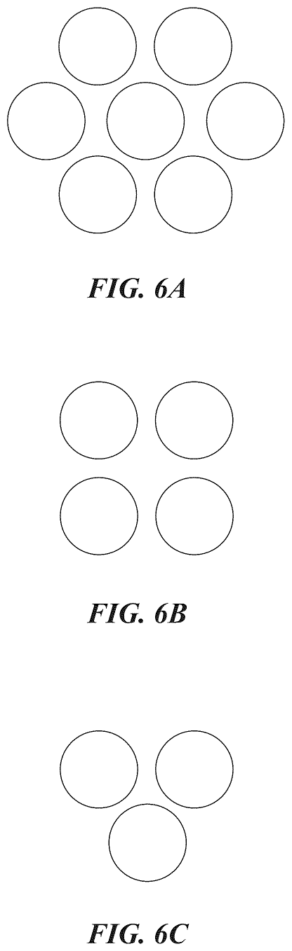

In some embodiments, the connectors with increased lateral dimension, as described in above examples shown in FIGS. 2A through 5F for critical signals transition, can be processed by a cluster vias etching and a vias merging process. For example, FIG. 6A through 6C illustrate various examples of lithography hard mask patterns for fabricating one or more cluster connector vias in semiconductor device assembly according to embodiments of the present technology. The various example patterns can be described or defined by an arrangement shape, a via diameter, a separation distance, and/or the like. FIG. 6A illustrates a pattern of seven circles aligned in a hexagon shape on a lithography mask, having one circle disposed in the center of the hexagon. In this example, each of the circles can have a diameter ranging from 400 nm to 700 nm. The distance between edges of neighboring circles can be up to 200 nm. In another example, the lithography mask can include four filled circles aligned in a square shape, as shown in FIG. 6B. In this example, each of the circles can have a diameter ranging from 500 nm to 800 nm. The distance between edges of neighboring circles can be up to 100 nm. In yet another example, the lithography mask can include three filled circles aligned in a triangle shape, as shown in FIG. 6C. Here, each of the circles can have a diameter ranging from 600 nm to 900 nm, with a distance between edges of neighboring circles being up to 100 nm.

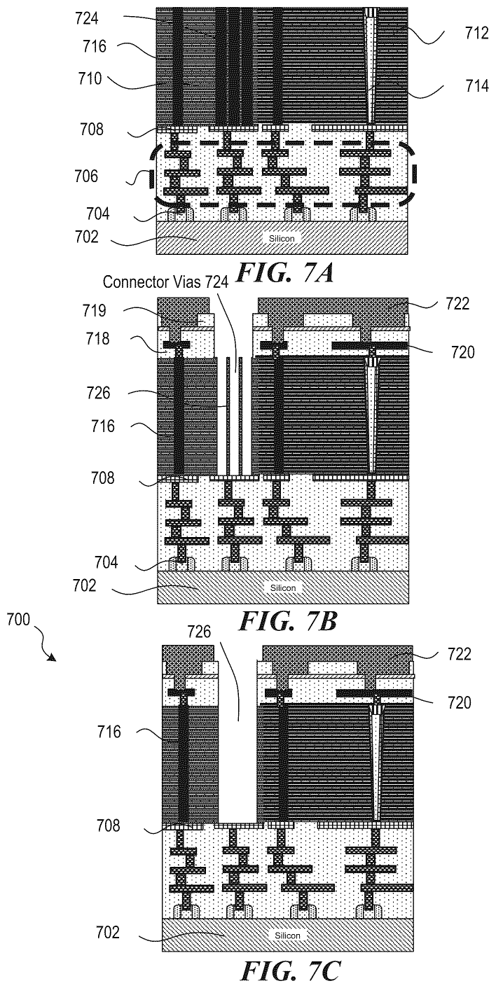

FIGS. 7A through 7C depict stages of processing to fabricate a semiconductor device 700 in a CuA architecture by utilizing the lithography mask, e.g., similar to the lithography mask described in FIGS. 6A through 6C, according to embodiments of the present technology. As shown in FIG. 7A, a lithography mask including a cluster of circles, e.g., the pattern of FIG. 6A, can be applied on the semiconductor device 700. Specifically, the CuA semiconductor device 700 can include a substrate 702, a plurality of CMOS devices 704 disposed above the substrate 702, and a plurality of intermediate metal layers 706. The semiconductor device 700 can also include a memory region 712 and a non-memory region 710 that are disposed above the intermediate metal layers 706. In this example, the memory region 712 and the non-memory region 710 can be patterned by using the lithography mask to form a cluster of connector vias 724 in the non-memory region 710. In some other examples, the cluster of connector vias 724 can be formed in the memory region 712. After the patterning processes, conductive materials such as aluminum, tungsten, cobalt, nickel, or any other suitable conductive materials can be filled into the semiconductor device 700 to form the connector 716 and the pillar 714. In this example, the pillars 714 may have a width ranging from 0.1 μm to 0.15 μm. In addition, the connectors 716 may have a width close to 0.5 μm.

In a next stage and as shown in FIG. 7B, RDL layer 318 can be formed by patterning a dielectric layer 718 deposited on the semiconductor device 700 and filling with conductive materials. After that, another dielectric layer 719 can be deposited there above and the dual damascene technique can be utilized to pattern the dielectric layers 718 and 719 to form trenches and vias. Once the dual damascene structures are formed, the trenches and vias can be further protected by photo resist 722 deposited there on. In a following process, the dielectric layers 718 and 719 can be patterned to form an opening right above the cluster of connector vias 724. The conductive materials within the cluster of connector vias 724 can be etched out through the opening using a selective etching process, such as a wets etching process or a RIE etching process. As shown in FIG. 7B, residue pillars 726 can exist once the conductive materials are removed from the cluster of contact vias 724. Each of the residue pillars 726 can have a lateral dimension similar to the distance between edges of neighboring circles as shown in FIG. 6C, e.g., up to 100 nm. In this example, the residue pillars 726 can contain dielectric materials such as silicon oxide or silicon nitride.

To merge the cluster of connector vias 724 and form a connector via 726 with a larger diameter, an etching process such as anisotropic wets etch or a directional RIE etch process can be conducted on the semiconductor wafer 700. Specifically, the etching process can delivery etchant chemistries into the cluster contact vias 724 and selectively remove the residue pillars 726 from the semiconductor device 700. In this example, the etching process can continue until the clusters of connector vias 724 are merged. As shown in FIG. 7C, the connector via 726 can be formed once all the residue pillars 726 are etched away and the clusters of contact vias 724 are fully merged. The resulting connector via 726 may have one or more traits characteristic of the additional etching (e.g., the merging) process, such as a profile shaping having a wider bottom portion. After that, conductive materials such as copper (not shown) can be filled into the connector via 726 to form a connector for critical signals transition. In the present technology, the cluster connector vias etching and merging processes described above could be conducted on a memory array wafer, e.g., the memory array wafer described in FIGS. 3A through 5F, which can be further bonded to a CMOS wafer for a F2F POA semiconductor device assembly.

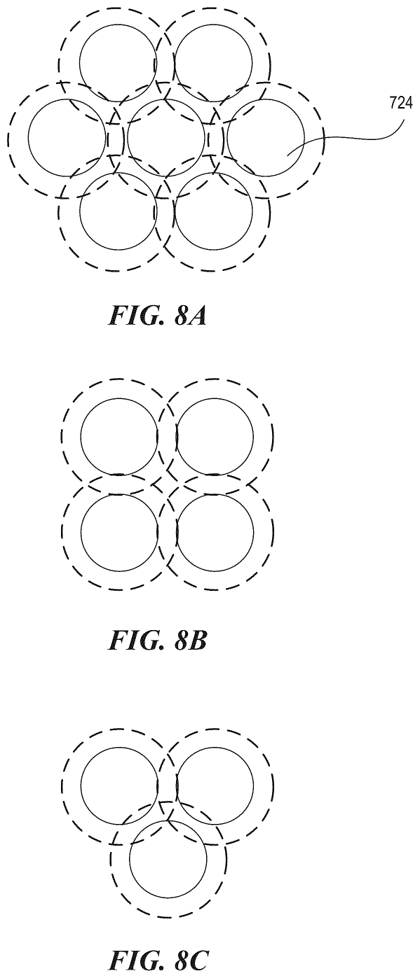

FIGS. 8A through 8C illustrate merging of the cluster connector vias 724 corresponding to the lithography mask patterns of FIGS. 6A through 6C, respectively, according to embodiments of the present technology. As described, the cluster of connector vias, such as the cluster connector vias 724, can be merged by removing the residue pillars 726 disposed there between. In FIGS. 8A to 8C, the cluster connector vias are shown in solid circles, which can be further expanded laterally (shown in dashed line circles) during the cluster vias etching process. In this example, one or more of the cluster connect vias can have a tapered sidewall. Accordingly, the cluster vias etching process can include an over etching portion to make sure the bottom regions of the cluster connector vias are all merged. Alternatively, the etching process can be turned to achieve a higher etch rate at the bottom portion of the cluster connector vias, in comparison to the top portion of the cluster connector vias. In a cross sectional view, the connector via 726 and the connector filled with conductive material can have a profile including at least two arcs. In particular, the connector via 726 and corresponding connector can have six arcs, four arcs, or three arcs corresponding to the seven circles, four circles, and three circles patterns of the lithography mask described in FIG. 6A through 6C, respectively.

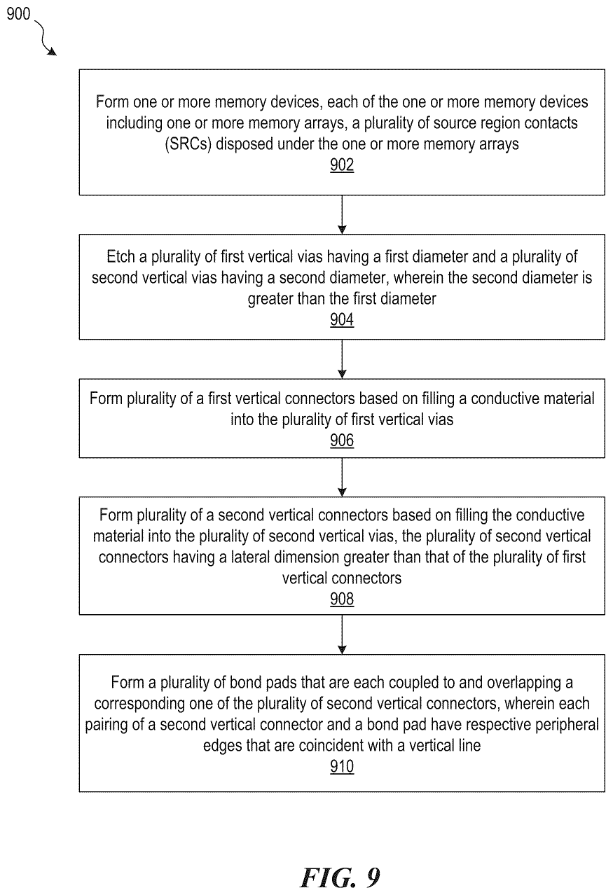

FIG. 9 is a flow chart illustrating a method 900 of processing a semiconductor device assembly with one or more connectors according to embodiments of the present technology. In other words, the method 900 can be for manufacturing one or more of the semiconductor device assemblies described above (e.g., one or more of the devices 200 of FIG. 200, 300 of FIG. 3C, 400 of FIG. 4C, 500 of FIG. 5E, and 700 of FIG. 7C).

For example, the method 900 can include forming one or more memory devices as illustrated at block 902. Each of the formed memory device can include one or more memory arrays. The memory device can include SRCs coupled to (e.g., disposed under) one or of the memory arrays, such as illustrated in FIGS. 2A, 3A, 4A, 5A, and 7A.

At block 904, the method 900 can form vias in the formed memory devices. For example, the manufacturing process illustrated in block 904 can include etching (1) a plurality of first vertical vias having a first diameter and (2) a plurality of second vertical vias having a second diameter. The second diameter can be greater than the first diameter.

At block 906, the method 900 can include forming one or more vertical electrical connectors using the formed vias. For example, the manufacturing process illustrated in block 906 can include filling a conductive material into the plurality of first vertical vias, thereby forming a plurality of first vertical connectors.

At block 908, the method 900 can include forming one or more vertical electrical connectors having a different width. For example, the manufacturing process illustrated in block 908 can include filling a conductive material into the plurality of second vertical vias, thereby forming a plurality of second vertical connectors that have greater lateral dimensions than those of the first vertical connectors.

At block 910, the method 900 can including forming electrical connections to/from the formed vertical connectors. For example, the manufacturing process illustrated in block 910 can include forming a plurality of bond pads that are each coupled to and overlapping a corresponding one of the vertical connectors (e.g., first and/or second vertical connectors). Each pairing of a second vertical connector and a wafer-to-wafer band pad can have respective peripheral edges aligned (e.g., coincident with a vertical line/plane).

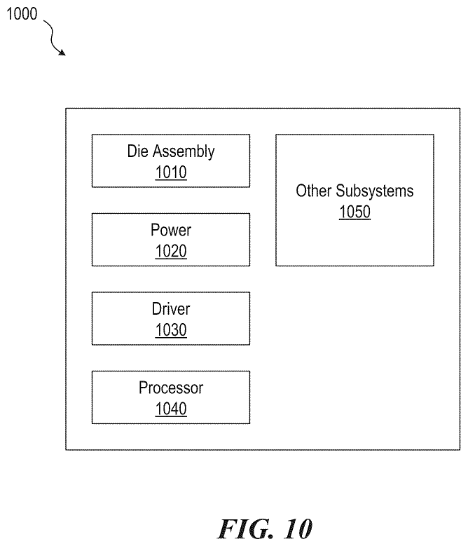

Any one of the semiconductor structures described above with reference to FIGS. 1A-8C can be incorporated into any of a myriad of larger and/or more complex systems, a representative example of which is system 1000 shown schematically in FIG. 10. The system 1000 can include a semiconductor device 1010, a power source 1020, a driver 1030, a processor 1040, and/or other subsystems or components 1050. The semiconductor device 1010 can include features generally similar to those of the semiconductor devices described above and can therefore include the connectors described in the present technology. The resulting system 1000 can perform any of a wide variety of functions, such as memory storage, data processing, and/or other suitable functions. Accordingly, representative systems 1100 can include, without limitation, hand-held devices (e.g., mobile phones, tablets, digital readers, and digital audio players), computers, and appliances. Components of the system 1000 can be housed in a single unit or distributed over multiple, interconnected units (e.g., through a communications network). The components of the system 1000 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a substrate;
a plurality of functional devices disposed above the substrate; and
a memory device disposed above the plurality of functional devices, the memory device including:
one or more memory arrays,
a plurality of first vertical electrical connectors having a first diameter and extending vertically, and
a plurality of second vertical electrical connectors having a second diameter and extending vertically, wherein the second diameter is greater than the first diameter.

2. The semiconductor device assembly of claim 1, further comprising a plurality of source region contacts (SRCs) disposed below the one or more memory arrays, wherein the plurality of second vertical electrical connectors pass through corresponding memory arrays, and wherein at least one of the plurality of second vertical electrical connectors is connected to a corresponding SRC.

3. The semiconductor device assembly of claim 2, wherein each of the one or more memory arrays includes a memory region and a non-memory region, and wherein the plurality of second vertical electrical connectors pass through non-memory regions of corresponding memory arrays.

4. The semiconductor device assembly of claim 1, wherein the second diameter of the plurality of second vertical electrical connectors is greater than the first diameter of the plurality of first vertical electrical connectors by a factor of 2 or greater.

5. The semiconductor device assembly of claim 1, wherein the first diameter of the plurality of first vertical electrical connectors is 900 nm or less, and wherein the second diameter of the plurality of second vertical electrical connectors is 1.5 μm or greater.

6. The semiconductor device assembly of claim 1, wherein the plurality of second vertical electrical connectors have a length, and wherein the second diameter of the second vertical electrical connectors is associated with the length to form an aspect ratio of the second vertical electrical connectors being 10:1 or less.

7. The semiconductor device assembly of claim 1, wherein the plurality of second vertical electrical connectors extend at least partially through the one or more memory array.

8. The semiconductor device assembly of claim 1, wherein each of the plurality of second vertical electrical connectors has a cross-sectional shape with two or more arcs.

9. The semiconductor device assembly of claim 1, further comprising a plurality of wafer-to-wafer bond pads that are each coupled to and overlapping a corresponding one of the plurality of second vertical electrical connectors, wherein each pairing of a second vertical electrical connector and a wafer-to-wafer bond pad have respective peripheral edges that are coincident with a vertical line.

10. A semiconductor apparatus, comprising:
a top portion including a first wafer-to-wafer bond pad and a second wafer-to-wafer bond pad configured to interface with one or more external circuits;
a lower portion including one or more functional circuits with a first connection point and a second connection point;
a first vertical connector extending vertically and electrically coupling the first connection point to the first wafer-to-wafer bond pad, wherein the first vertical connector has a first lateral dimension; and
a second vertical connector extending vertically and electrically coupling the second connection point to the second wafer-to-wafer bond pad, wherein the second vertical connector has a second lateral dimension that is greater than the first lateral dimension.

11. The semiconductor apparatus of claim 10, wherein the second lateral dimension of the second vertical connector is greater than the first lateral dimension of the first vertical connector by a factor of 2 or greater.

12. The semiconductor apparatus of claim 10, wherein the first lateral dimension of the first vertical connector is 900 nm or less, and wherein the second lateral dimension of the second vertical connector is 1.5 μm or greater.

13. The semiconductor apparatus of claim 10, wherein the second vertical connector has an aspect ratio being 10:1 or less.

14. The semiconductor apparatus of claim 10, wherein the second vertical connector has a cross-sectional shape with two or more arcs.

15. A method of forming a semiconductor device assembly, comprising:
forming one or more memory devices, each of the one or more memory devices including one or more memory arrays, a plurality of source region contacts (SRCs) disposed under the one or more memory arrays;
etching a plurality of first vertical vias having a first diameter and a plurality of second vertical vias having a second diameter, wherein the second diameter is greater than the first diameter;
forming plurality of a first vertical connectors based on filling a conductive material into the plurality of first vertical vias;
forming plurality of a second vertical connectors based on filling the conductive material into the plurality of second vertical vias, the plurality of second vertical connectors having a lateral dimension greater than that of the plurality of first vertical connectors; and
forming a plurality of wafer-to-wafer bond pads that are each coupled to and overlapping a corresponding one of the plurality of second vertical connectors, wherein each pairing of a second vertical connector and a wafer-to-wafer bond pad have respective peripheral edges that are coincident with a vertical line.

16. The method of claim 15, wherein forming the plurality of second vertical connectors includes:
filling the conductive material into sidewalls and bottom surface of the plurality of second vertical vias;
filling a sacrificial material into a space between the conductive material attached to the sidewalls and the bottom surface;
forming a hard mask layer above the one or more memory devices, the hard mask layer having a plurality of openings corresponding to the plurality of second vertical vias;
removing the conductive material and the sacrificial material from the plurality of second vertical vias; and
refilling, after the removal, the conductive material into the plurality of second vertical vias.

17. The method of claim 15, further comprising:
forming a plurality of functional devices on a substrate; and
forming a plurality of intermediate conductive layers above each of the plurality of functional devices, the plurality of intermediate conductive layers interconnecting the plurality of functional devices to corresponding SRCs, wherein the one or more memory devices are formed above the plurality of functional devices.

18. The method of claim 17, wherein the plurality of second vertical connectors is configured to transmit critical signals, between the plurality of wafer-to-wafer bond pads and the plurality of functional devices, with a resistance lower than the plurality of first vertical connectors.

19. The method of claim 15, wherein etching of the plurality of second vertical vias includes:
etching a plurality of cluster of vertical vias through the memory array, each of the cluster of vertical vias being adjacent and having a plurality of residue pillars disposed there between, and
etching the plurality of reside pillars to merge each of the cluster of vertical vias to form the plurality of second vertical vias, each of the plurality of second vertical vias has a cross-sectional shape with two or more arcs.

20. The method of claim 15, wherein the one or more memory devices are formed on a memory wafer, wherein a frontside surface of the memory wafer is bonded to a frontside surface of a logic wafer, through a hybrid bonding technique, to form a face-to-face (F2F) wafer-on-wafer (WoW) bonding scheme.
